(19) United States
(12) Patent Application Publication
(10) Pub. No.: US 2023/0378146 A1
(43) Pub. Date: Nov. 23, 2023

(54) MICROELECTRONIC DEVICE PACKAGE WITH INTEGRAL PASSIVE COMPONENT

(71) Applicant: Texas Instruments Incorporated, Dallas, TX (US)

(72) Inventors: John Carlo Molina, Limay (PH); Julian Carlo Barbadillo, Mabalacat City (PH); Chun Ping Lo, Allen, TX (US); Sylvester Ankamah-Kusi, Dallas, TX (US); Rajen Murugan, Dallas, TX (US); Thomas Kronenberg, Dallas, TX (US); Jonathan Noquil, Plano, TX (US); Guangxu Li, Allen, TX (US); Blake Travis, Richardson, TX (US); Jason Colte, Mabalacat City (PH)

(21) Appl. No.: 18/320,102

(22) Filed: May 18, 2023

Related U.S. Application Data
(60) Provisional application No. 63/344,383, filed on May 20, 2022.

(51) Int. Cl. H01L 25/16; H01L 23/498; H01L 23/31; H01L 23/00; H01L 23/495; H01L 21/48; H01L 21/56

(52) U.S. Cl. CPC H01L 25/16; H01L 23/49822; H01L 28/40; H01L 23/3121; H01L 24/16; H01L 23/49562; H01L 21/4857; H01L 21/56; H01L 2224/16227

(57) ABSTRACT

An example microelectronic device package includes: a multilayer package substrate comprising routing conductors spaced by dielectric material, the multilayer package substrate having a device side surface and an opposing board side surface, and having a recessed portion extending from the device side surface and exposing routing conductors beneath the device side surface of the multilayer package substrate; a semiconductor die mounted to the device side surface of the multilayer package substrate and coupled to the routing conductors; a passive component mounted to the routing conductors exposed in the recessed portion of the multilayer package substrate; and mold compound covering the semiconductor die, the passive component, and a portion of the multilayer package substrate.

### CROSS-REFERENCE TO RELATED APPLICATIONS

This application claims the benefit of and priority to U.S. Provisional Application No. 63/344,383, filed May 20, 2022, which Application is hereby incorporated herein by reference in its entirety.

### TECHNICAL FIELD

This disclosure relates generally to microelectronic device packages, and more particularly to microelectronic device packages including one or more integral passive components and, in some examples, one or more semiconductor devices.

### BACKGROUND

Processes for producing microelectronic device packages include mounting a semiconductor die to a package substrate and covering the electronic devices with a dielectric material, such as a mold compound, to form packaged devices.

Incorporating passive components such as capacitors, inductors, and coils with semiconductor devices in a microelectronic device package is desirable. Capacitors are of particular interest when packaging power field effect transistors (power FETs). Capacitors are used with power FETs in many applications. Additional applications include packaging using passive components such as inductors and coils with semiconductor devices to increase performance and reduce board area, and to make the microelectronic device package with the passives needed for a normal configuration increases ease of use and reduces circuit design time. Often a passive component is mounted next to, or mounted on or over a completely packaged semiconductor device.

Prior approaches include the use of expensive printed circuit board (PCB) package substrates, which are sometimes used inside a molded device package with mold compound covering the semiconductor devices and the passive components. Molded packages with passives on a board or substrate can result in the use of relatively tall or thick molded packages, extra thickness of the molded package is needed because the height of the passive components is much thicker than that of the semiconductor device dies. The extra mold compound thickness needed to cover the passive component increases mold compound stress and increases the likelihood of mold compound cracks during manufacture or due to thermal expansion in the field. A solution to reducing the mold compound cracking defects is to reduce the volume of the mold compound, that is, to form thinner mold compound over the devices, and thus form a thinner microelectronic device package. Some desirable passive components for integration are substantially thicker than target mold compound thicknesses, making these solutions impractical or unreliable. Adding passive components to packaged semiconductor devices using brackets or mounts on the exterior of semiconductor device packages can be done, but these solutions are relatively high in cost and require substantial package volume in a system. Making molded microelectronic device packages that are efficient and cost-effective while including passive components within the microelectronic device packages remains challenging.

### SUMMARY

In a described example, a microelectronic device package includes a multilayer package substrate comprising routing conductors spaced by dielectric material, the multilayer package substrate having a device side surface and an opposing board side surface, and having a recessed portion extending from the device side surface and exposing routing conductors beneath the device side surface of the multilayer package substrate. A semiconductor die is mounted to the device side surface of the multilayer package substrate and coupled to the routing conductors. A passive component is mounted to the routing conductors exposed in the recessed portion of the multilayer package substrate; and mold compound covers the semiconductor die, the passive component, and a portion of the multilayer package substrate.

In a further described example, a microelectronic device package includes a package substrate having a device side surface and an opposing board side surface, and having a portion configured for mounting a passive component on the device side surface. A semiconductor die is mounted to the device side surface of the package substrate. Mold compound covers the device side surface of the package substrate and covers the semiconductor die. A recess extends into the mold compound exposing the portion of the package substrate configured for mounting a passive component on the device side surface. A passive component is mounted in the recess in the mold compound and to the package substrate, the passive component coupled to the semiconductor die.

In a described example method, the method includes: forming a multilayer package substrate comprising trace level conductors in layers spaced from one another by dielectric material, connection level conductors between the trace level conductors and coupling the trace level conductors and extending through the dielectric material, a device side surface for mounting a semiconductor die, and a board level surface opposite the device side surface. The method continues by forming a recessed portion extending into the multilayer package substrate from the device side surface, the recessed portion exposing conductors of a trace level conductor beneath the device side surface configured for mounting a passive component. A semiconductor die is mounted over the device side surface of the multilayer package substrate, the semiconductor die coupled to the trace level conductors. A passive component is mounted in the recessed portion of the multilayer package substrate, the passive component coupled to the semiconductor die by the trace level conductors. The method continues by covering the semiconductor die, the device side surface of the multilayer package substrate, and the passive component with mold compound to form a microelectronic device package.

In another described method example, the method includes: mounting a semiconductor die over a device side surface of a package substrate, the package substrate having a board side surface opposite the device side surface, and having a portion for mounting a passive component to the device side surface spaced from the semiconductor die; covering the semiconductor die and the device side surface of the multilayer package substrate with mold compound; forming a recess into the mold compound exposing the portion of the package substrate for mounting a passive component; and mounting a passive component to the portion of the package substrate exposed in the recess in the mold compound.

### BRIEF DESCRIPTION OF THE DRAWINGS

FIGS. 1A-1B illustrate, in a projection view and a close-up projection view, respectively, semiconductor dies on a semiconductor wafer and an individual semiconductor die from the semiconductor wafer, for use with the arrangements.

FIGS. 2A-2B illustrate, in a projection view and a cross-sectional view, respectively, a microelectronic device package of an example arrangement.

FIGS. 3A-3B illustrate, in cross-sectional views, microelectronic device packages of alternative arrangements where a recess is formed into a multilayer package substrate and an embedded trace substrate, respectively, with a passive component mounted in the recess.

FIGS. 4A-4B illustrate, in a series of cross-sectional views, the major steps in manufacturing a multilayer package substrate that can be used in the arrangements.

FIG. 5A illustrates, in a cross-sectional view, an example passive component that can be used in the arrangements, FIG. 5B illustrates in a cross-sectional view, a microelectronic device package including the example passive component of FIG. 5A in an example arrangement, and FIGS. 5C-5G illustrate, in a cross-sectional view, selected steps in forming a microelectronic device package of an arrangement.

FIGS. 6A-6F illustrate, in a series of cross-sectional views, selected steps for forming additional example arrangements.

FIGS. 7A-7D illustrate, in a series of cross-sectional views, selected steps for an alternative arrangement.

FIG. 8 illustrates, in a flow diagram, selected steps of a method for forming a multilayer package substrate for use in example arrangements.

FIG. 9 illustrates, in another flow diagram, selected steps of a method for forming arrangements.

FIG. 10 illustrates, in an additional flow diagram, selected steps of an additional method for forming arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. When semiconductor devices are fabricated on a semiconductor wafer and then individually separated from the semiconductor wafer, the individual units are referred to as “semiconductor dies.” A semiconductor die is also a semiconductor device.

The term “passive component” is used herein. As used herein, a passive component is a packaged component without active devices, for example, a resistor, capacitor, inductor, coil, diode, or sensor, and which is provided in a package configured for mounting to a module or board. Examples useful in the arrangements include ceramic capacitors, ceramic packages with resistors, inductors, or coils. The passive components can have two or more terminals, many have two terminals. The passive components can have studs for solder mounting to a board. In particular examples, the passive components are “0402” capacitors. 0402 passives have a length of about 1 millimeter (about 0.04 inches), and a width and thickness of about 0.5 millimeters (about 0.02 inches). Having a standard size package enables use of packaged components from a variety of vendors in manufacturing existing designs without need for changing board or trace layouts, for example.

The term “microelectronic device package” is used herein. A microelectronic device package has at least one semiconductor die electrically coupled to terminals, and has a package body that protects and covers the semiconductor die. The microelectronic device package can include additional elements, in example arrangements a passive component is included. Passive components such as capacitors, resistors, and inductors or coils can be included. In some arrangements, multiple semiconductor dies can be packaged together. The semiconductor die is mounted to a package substrate that provides conductive leads; a portion of the conductive leads form the terminals for the packaged device. The semiconductor die can be mounted with a device side facing towards device side surface of the package substrate using conductive post connects in a flip chip package. The microelectronic device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the terminals for the microelectronic device package.

The term “package substrate” is used herein. A package substrate is a substrate arranged to receive a semiconductor die and in the illustrated examples, other components, and to support the semiconductor die in a completed semiconductor device package. Package substrates useful with the arrangements include conductive lead frames, molded interconnect substrates (MIS), partially etched lead frames, pre-molded lead frames, embedded trace substrates (ETS), and multilayer package substrates. In some arrangements, a flip chip die mount is used for the semiconductor dies, where post connects that extend from bond pads on the semiconductor device are attached by a solder joint to conductive lands on the device side surface of the package substrate. The post connects can be solder bumps or other conductive materials such as copper or gold with solder on a distal end. Copper pillar bumps can be used. In alternative arrangements using wire bonded packages, bond wires can couple bond pads on the semiconductor dies to the leads on the device side surface of the package substrate.

The term “multilayer package substrate” is used herein. A multilayer package substrate is a substrate that has multiple conductor layers including trace level conductors, and which has connection level conductors extending through the dielectric material between the trace level conductor layers. In an example arrangement, a multilayer package substrate is formed in an additive manufacturing process by plating a patterned trace level conductor and then covering the trace level conductor with a layer of dielectric material. Grinding or thinning can be performed on the dielectric material to expose portions of the top surface of the layer of conductors from the dielectric material. Additional plating layers can be formed to add additional levels of trace level conductors, some of which are trace layers that are coupled to other trace layers in the dielectric materials by connection level conductors, and additional dielectric material can be deposited at each level and can cover the conductors. By using an additive or build-up manufacturing approach, and by performing multiple plating steps, multiple dielectric formation steps, and multiple grinding steps, a multilayer package substrate is formed with an arbitrary number of trace level conductor layers and connection level conductor layers between and coupling portions of the trace level conductor layers.

The term “embedded trace substrate” (ETS) is used herein. In an embedded trace substrate, trace conductor layers are spaced by prepreg laminated layers. The prepreg layers are dielectric material. Vias are formed through the prepreg layers between multiple layers of trace conductors and couple the trace conductor layers. In an example arrangement, an ETS is used as a package substrate with multiple trace layers, and a passive component is mounted to the ETS, and mold compound covers the ETS, a semiconductor die mounted to the ETS and a passive component. A recess is opened extending into the ETS from a device side surface to expose trace conductors at a trace level beneath the device side surface, and the passive component is mounted in the recess in the ETS, reducing the thickness of a mold compound needed to cover the passive component, and reducing the package thickness.

In an example multilayer package substrate used in an arrangement, copper, gold or tungsten conductors are formed by plating, and a thermoplastic material can be used as the dielectric material. The connector level conductors between trace level conductor layers can be of arbitrary shapes and sizes and can include rails and pads to couple trace layers with low resistance for power and high current signals. Unlike vias in a printed circuit board technology, the connection level conductors extending through the dielectric material are not formed by plating conductors in holes mechanically drilled through a dielectric material, which are limited in size and shape. Instead, in the arrangements, an additive build-up approach forms the connection level conductors plated during the additive manufacturing process, and thus the connection level conductors can have a variety of shapes and sizes. Multiple levels of trace level conductors and connection level conductors can be patterned as stacked conductors extending through the dielectric material, and these stacked conductors can form arbitrary shapes. Portions of the conductors on a board side surface of the multilayer package substrate can be exposed from the completed package to form terminals for the microelectronic device package, the terminals can be coupled to the semiconductor die or other components in the microelectronic device package by the other conductors in the multilayer package substrate.

In packaging microelectronic and semiconductor devices, mold compound may be used to partially cover a package substrate, to cover passive components, to cover a semiconductor die, and to cover the electrical connections from the semiconductor die to the package substrate. This molding process can be referred to as an “encapsulation” process, although some portions of the package substrates are not covered in the mold compound during encapsulation, for example terminals and leads are exposed from the mold compound to enable electrical connections to the packaged device. Encapsulation is often a compressive molding process, where thermoset mold compound such as resin epoxy can be used. A room temperature solid or powdered mold compound can be heated to a liquid state and then molding can be performed by pressing the liquid mold compound into a mold through runners or channels. Transfer molding can be used. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded together.

After the molding process is complete, the individual microelectronic device packages are cut apart from each other in a sawing operation by cutting through the mold compound and package substrate in saw streets formed between the devices. Portions of the package substrate leads are exposed from the mold compound package to form terminals for the packaged semiconductor device.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

The term “quad flat no-lead” (QFN) is used herein for a type of electronic device package. A QFN package has conductive leads that are coextensive with the sides of a molded package body, and in a quad package the leads are on four sides. Alternative flat no-lead packages may have leads on two sides or only on one side. These can be referred to as small outline no-lead (“SON”) packages. No-lead packaged electronic devices can be surface mounted to a board. Leaded packages can be used with the arrangements where the leads extend away from the package body and are shaped to form a portion for soldering to a board. A dual in line package (DIP) can be used with the arrangements. A small outline package (SOP) can be used with the arrangements. Small outline no-lead (SON) packages can be used, and a small outline transistor (SOT) package is a leaded package that can be used with the arrangements. Leads for leaded packages are arranged for solder mounting to a board. The leads can be shaped to extend towards the board and form a mounting surface. Gull wing leads, J-leads, and other lead shapes can be used. In a DIP package, the leads end in pin shaped portions that can be inserted into conductive holes formed in a circuit board, and solder is used to couple the leads to the conductors within the holes.

In the arrangements, a semiconductor die, such a power FET device, can be mounted to a package substrate in a microelectronic device package that includes an integral passive component. The semiconductor die can be coupled to the passive component by conductors of the package substrate. In an example arrangement, the passive component is at least one two-terminal capacitor. In additional example arrangements multiple passive components can be used. In additional example arrangements, the package substrate can be a two or more-layer multilayer package substrate or a laminate package substrate, and the multilayer package substrate can be used to mount the semiconductor die and to mount the passive component in a recessed portion. The packaged component can have a thickness greater than the thickness of the semiconductor die. By forming a recessed portion of the multilayer package substrate and positioning the passive component in the recess for mounting to the multilayer package substrate, the thickness of a mold compound of the microelectronic device package can be reduced (when compared to packaging the devices on a substrate without use of the arrangements). Reducing the thickness of the mold compound used in the package reduces mechanical stress due to the mold compound, reduces cracking defects in the microelectronic device packages, and increases reliability.

In still further arrangements, a package substrate is used to mount a semiconductor die on a device side surface, the package substrate having a portion for mounting a passive component alongside and spaced from the semiconductor die. The semiconductor die and the package substrate are covered with mold compound at a thickness sufficient to cover the semiconductor die for the package. A portion of the mold compound covering the package substrate is removed by an etch or laser ablation process to expose the portion for mounting the passive component. The passive component is mounted after molding, and is not covered by the mold compound. Additional material to protect the passive component can be deposited in the recess. Because the mold compound does not cover the passive component, a passive component with a thickness greater than that of the semiconductor die can be packaged with the semiconductor die without the need for a thicker mold compound, reducing the mold compound stress in the microelectronic device package. Use of the arrangements to mount the semiconductor die and the passive components allows for a microelectronic device package with integral passive devices with increased reliability over prior approaches.

In some example arrangements, an ETS or a multilayer package substrate has a device side surface, a semiconductor die mounted on a portion of the device side surface, and a recessed portion extending into the ETS or multilayer package substrate and spaced from the semiconductor die. A passive component is mounted in the recessed portion. A semiconductor die mounted to the device side surface of the package substrate can be coupled to the passive component by the conductive traces formed in trace layer conductors of the package substrate. In one example, the semiconductor die can be flip chip mounted to a device side surface of a multilayer package substrate. In some arrangements, the semiconductor die and the passive component in the multilayer package substrate can be completely covered by mold compound or another encapsulation material such as an epoxy or resin. In another arrangement, the semiconductor die is covered by the mold compound, while the passive component is not covered by the mold compound but instead extends above the top surface of the mold compound in the microelectronic device package.

In a particular example arrangement, a capacitor is mounted in a microelectronic device package with a semiconductor die. The capacitor has a thickness of about 0.5 millimeters, and in a particular example is an 0402 packaged capacitor, having a thickness of about 0.5 millimeters (about 0.02 inches) and a length of about 1 millimeter (about 0.04 inches). Other capacitors having various sizes can be used in additional arrangements. The overall package thickness in some example arrangements can be less than or equal to 0.65 millimeters. A package substrate used in the arrangements can have a thickness of less than or equal to about 0.2 millimeters. To achieve the desired overall package thickness using the capacitor with about 0.5 millimeters thickness, the capacitor is mounted in a recess in a package substrate, and a mold compound layer having a thickness of about 0.45 millimeters is used. Having a mold compound of a thickness less than that used in prior approaches to microelectronic device packages including the capacitors of this thickness reduces mold compound stress, and reduces defects caused by package cracking and delamination due to mold compound stress.

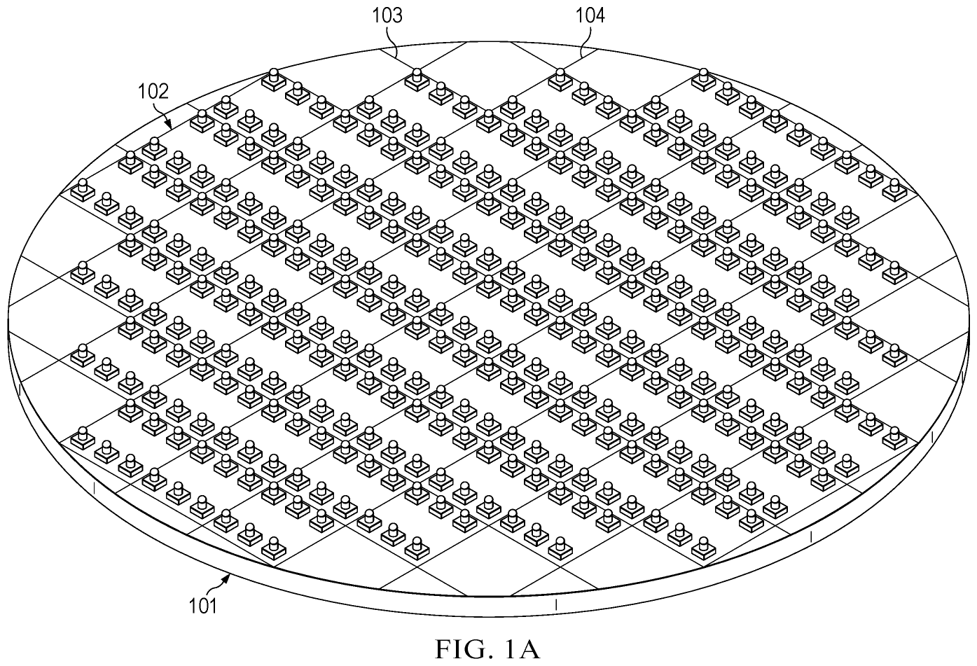

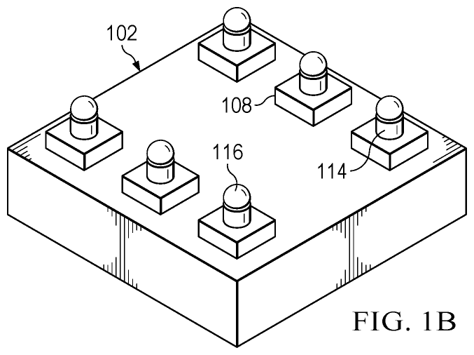

FIGS. 1A and 1B illustrate, in two projection views, a semiconductor wafer having semiconductor die devices formed on it that are configured for flip chip mounting, and an individual semiconductor die for flip-chip mounting, respectively. In FIG. 1A, a semiconductor wafer 101 is shown with an array of semiconductor dies 102 formed in rows and columns on a surface. The semiconductor dies 102 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another, and which run in parallel groups across the wafer 101, separate the rows and columns of the completed semiconductor dies 102, and provide areas for dicing the wafer 101 to separate the semiconductor dies 102 from one another.

FIG. 1B illustrates a single semiconductor die 102 taken from semiconductor wafer 101. Semiconductor die 102 includes bond pads 108, which are conductive pads that are electrically coupled to devices (not shown) formed in the semiconductor die 102. Conductive post connects 114 are shown extending away from a proximate end on the bond pads 108 on the surface of semiconductor die 102 to a distal end, and solder bumps 116 are formed on the distal ends of the conductive post connects 114. The conductive post connects 114 can be formed by electroless plating or electroplating. In an example, the conductive post connects 114 are copper, and have solder bumps 116 on the distal ends, and are sometimes referred to as “copper pillar bumps.” Copper pillar bumps can be formed by sputtering a seed layer over the surface of the semiconductor wafer 101, forming a photoresist layer over the seed layer, using photolithography to expose seed layer over the bond pads 108 in openings in the layer of photoresist, plating the copper conductive post connects 114 on the bond pads, and plating a lead solder or a lead-free solder such as an tin, silver (SnAg) or tin, silver, copper (SnAgCu) or SAC solder to form solder bumps 116 on the copper conductive post connects 114. In an alternative approach, solder bumps or particles may be dropped onto the distal ends of the copper pillar bumps and then reflowed in a thermal process to form bumps. Other conductive materials can be used for the conductive post connects in an electroplating or electroless plating operation, including gold, silver, nickel, palladium, or tin, for example. Not shown for clarity of illustration are under-bump metallization (UBM) portions which can be formed over the bond pads to improve plating and adhesion between the conductive post connects 114 and the bond pads 108. After the plating operations, the photoresist is then stripped, and the excess seed layer is etched from the surface of the wafer. Polyimide (PI) (not shown) or other dielectric can be applied between the conductive post connects to protect the semiconductor die 102 and the conductive post connects 114. The semiconductor dies 102 are then separated by dicing, or are singulated, using the scribe lanes 103, 104 (see FIG. 1A).

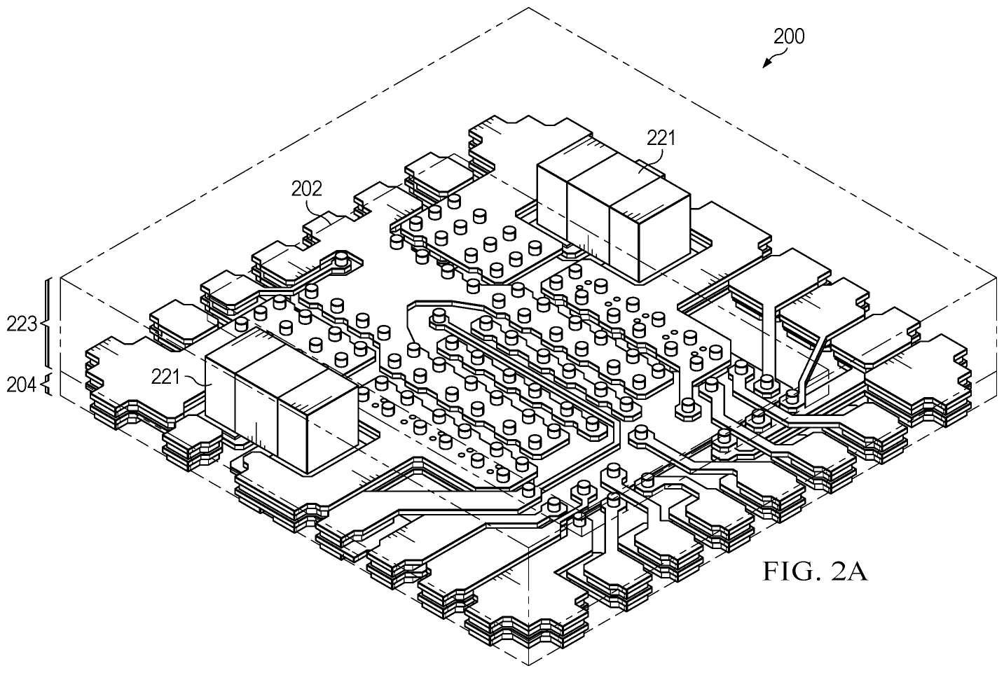

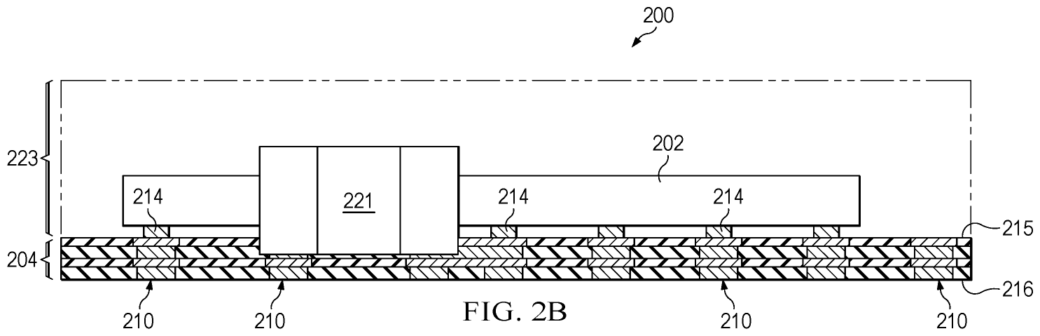

FIGS. 2A-2B illustrate, in a projection view and a cross-sectional view, respectively, a microelectronic device package of an arrangement. In FIG. 2A, the microelectronic device package 200 is shown in a projection view. In the illustrated example, the microelectronic device package 200 is a quad flat no-lead (QFN) package. A package substrate 204, which in the illustrated example is a multilayer package substrate, is shown covered by a mold compound 223. Passive components 221 are shown mounted to a device side surface 215 of the multilayer package substrate, and a semiconductor die 202 is shown flip chip mounted to the multilayer package substrate 204 by post connects 214 (solder joints, not shown for simplicity of illustration, couple the post connects to the multilayer package substrate 204, see for example solder bumps 116 in FIG. 1B). In FIG. 2B, in the cross-sectional view, the passive components 221 are shown extending into the multilayer package substrate from the device side surface 215. By placing the passive components into recesses formed in the multilayer package substrate, the use of the arrangements lowers the height above the multilayer package substrate that the passive component 221 extends. Mold compound 223 covers the semiconductor die 202, the device side surface 215 of the multilayer package substrate 204, and the passive component 221. A board side surface 216 of the multilayer package substrate 204, which is opposite the device side surface 215, includes terminals 210 formed of portions of the conductors of the multilayer package substrate 204. The terminals 210 are exposed for use in mounting the device to a board or module. Use of the arrangements enables a thinner mold compound 223 to cover the passive components 221, and further enables a resulting thinner microelectronic device package 200 (when compared to a microelectronic device package formed without the use of the arrangements).

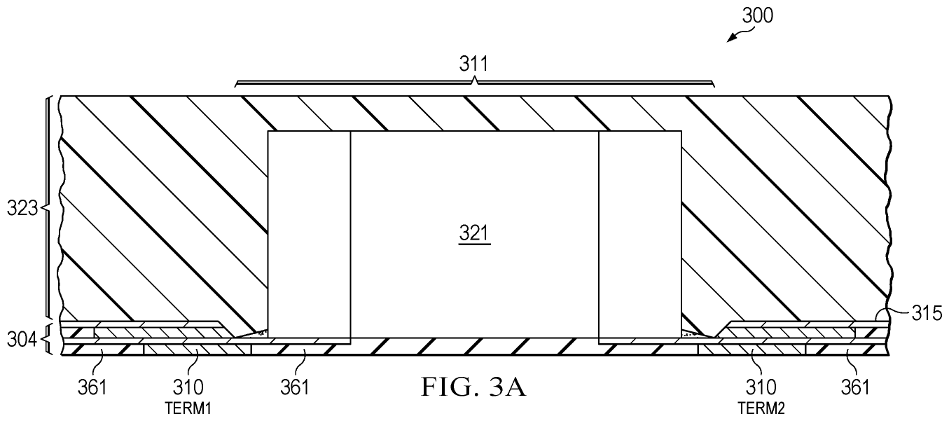

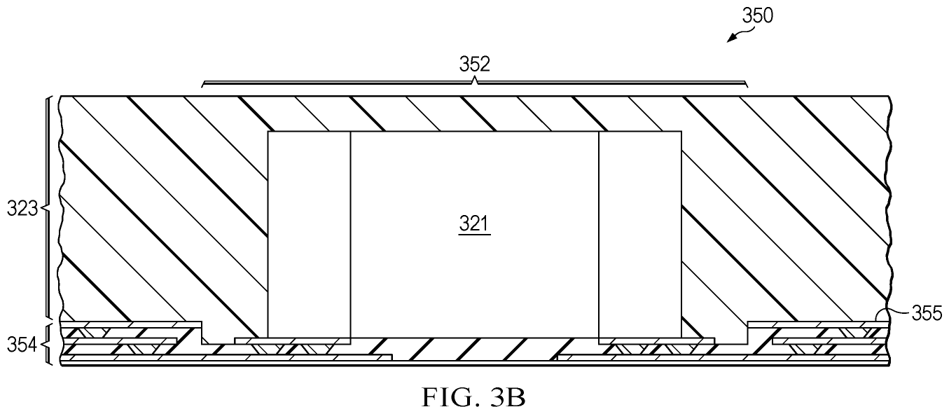

FIGS. 3A-3B illustrate two additional example arrangements in cross-sectional views. FIG. 3A illustrates an additional example microelectronic device package 300 including a passive component 321. Mold compound 323 is shown covering the passive component 321 which is mounted in a recess 311 in the multilayer package substrate 304. The passive component 321 has terminals soldered to trace level conductors in the multilayer package substrate 304, the trace level conductors are labeled “TERM1” and “TERM2.” In an example, the trace level conductors TERM1 and TERM2 can be configured as a power conductor and a ground conductor, respectively, where the passive component 221 is a capacitor coupled in a circuit as a bypass capacitor between the power and ground conductor. Bypass capacitors can couple alternating current (“AC”) signals or switching noise on a direct current (“DC”) signal to ground, and are often used in power circuits to reduce noise. Other circuit configurations can be used in the arrangements; and the passive component 321 can be an inductor, coil, diode, resistor, sensor or other passive component.

In the arrangement illustrated FIG. 3A, a metal etch, described in further detail below, can be used to remove trace level conductor material from recess 311 starting from the device side surface 315 of the multilayer package substrate 304. The metal etch is used to create the recessed portion for mounting the passive component 321. As the passive component is mounted to trace conductors at a conductor layer that lies beneath the device side surface 315 of the multilayer package substrate 304, the height above the device side surface of 315 that the passive component 321 extends is lessened, so that the mold compound 323 can be thinner while covering the passive component 321 and a semiconductor die (not shown in the cross-section of FIG. 3A) mounted on the device side surface of the multilayer package substrate 304. Terminals 310 are formed of a conductor layer in the multilayer package substrate 304.

The multilayer package substrate 304 is an example package substrate that can be used with the arrangements. In FIG. 3A, the multilayer package substrate 304 has a device side surface 315 and a board side surface 316. Trace level conductors are formed spaced from one another by dielectric material 361, the trace level conductor layers are patterned for making horizontal connections, and connection level conductor layers form connections between the trace level conductor layers and extend through the dielectric material 361 that is disposed over and between the trace level conductor layers. The dielectric material 361 can be a thermoplastic material such as Ajinomoto build-up film (ABF), other useful dielectric materials for the multilayer package substrate include acrylonitrile butadiene styrene (ABS), acrylonitrile styrene acrylate (ASA), or epoxy resin, such as epoxy resin mold compound. Electronic mold compound (EMC) is an example thermoset epoxy resin mold compound. Ajinomoto build-up film is commercially available from Ajinomoto Co., Inc., 15-1 Kyobashi 1-chome, Tokyo, Japan 104-8315. In a build-up manufacture of the multilayer package substrate using ABF, ABF is applied over plated conductors in a laminating process. By repeatedly plating and patterning conductors, and applying the ABF in layers, a multilayer package substrate can be formed.

In contrast to vias used in PCB manufacture, the connection level conductor layers used in the multilayer package substrates of the arrangements are formed in build-up plating processes and are formed similar to the processes used in forming the trace level conductor layers, simplifying manufacture, and reducing costs. In addition, the connection level conductor layers in the arrangements can be arbitrary shapes, such as rails, columns, or posts, and the rails can be formed in continuous patterns to form electric shields, tubs, or tanks, and can be coupled to grounds or other potentials, isolating regions of the multilayer package substrate from one another. Thermal performance of the microelectronic device packages of example arrangements can be improved by use of the connection level conductor layers to form thermally conductive columns, sinks or rails that can be coupled to thermal paths on a system board to increase thermal dissipation from the semiconductor devices mounted on the multilayer package substrate.

FIG. 3B illustrates another arrangement using an ETS package substrate. In FIG. 3B, a microelectronic device package 350 is shown with a passive component 321, which can be a capacitor, inductor, resistor, coil, diode or sensor, is shown mounted to a device side surface 355 of the ETS package substrate 354. The ETS substrate has a recess 352 that can be formed by laser ablation or etch processes to expose traces at a conductor layer beneath the device side surface 355. The passive component 321 can be mounted to the ETS in the recess prior to the mold compound 323 being formed over the device side surface 355 of the ETS substrate 354. A semiconductor die (not visible in the cross-sectional view in FIG. 3B) is mounted to the device side surface 355 of the ETS substrate 354 and is also covered by the mold compound 323. Because the passive component 321 is placed in the recess 352, the mold compound 323 thickness needed to cover the passive component, and including a clearance thickness, is reduced (when compared to packaged including the passive component formed without the use of the arrangements). Reducing the mold compound thickness reduces mold compound stress, and reduces package crack and delamination defects.

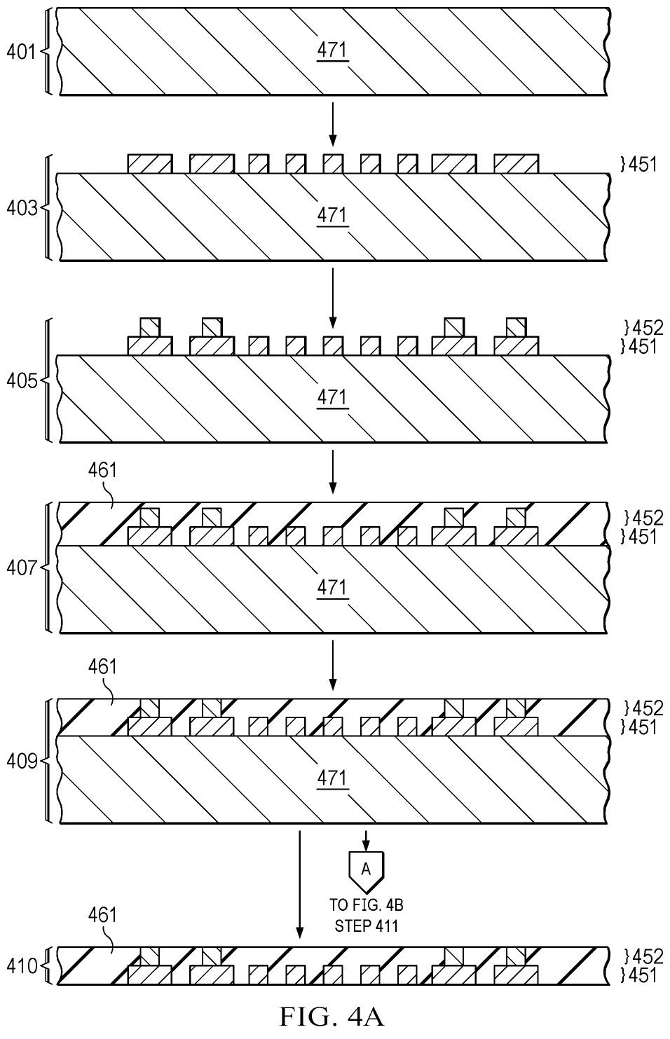

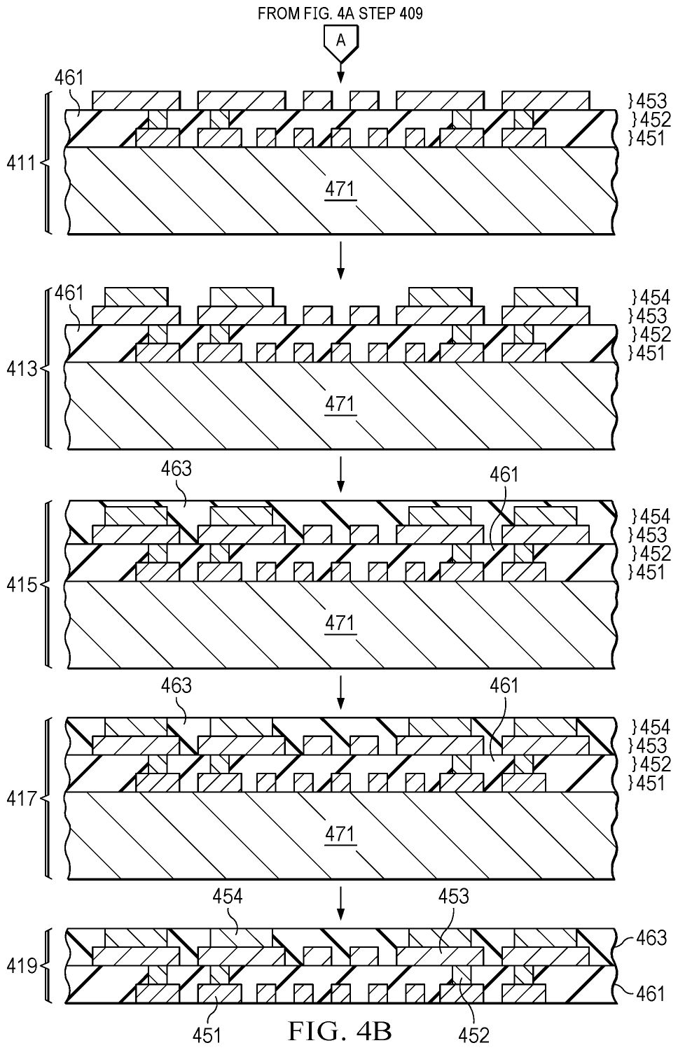

FIGS. 4A-4B illustrate, in a series of cross-sectional views, selected steps for a method for forming a multilayer package substrate such as the multilayer package substrate 304 in FIG. 3A that is useful with the arrangements. In FIG. 4A, at step 401, a metal, semiconductor or glass carrier 471 is readied for a plating process. The carrier 471 can be stainless steel, steel, aluminum or another metal or can be a semiconductor wafer or a glass that will support the multilayer package substrate layers during plating and molding steps, the multilayer package substrate is then removed, and the carrier 471 can be discarded or can be cleaned for use in additional manufacturing processes.

At step 403, a first trace level conductor layer 451 is formed by plating. In an example process, a seed layer is deposited over the surface of carrier 471, by sputtering, chemical vapor deposition (CVD) or other deposition step. A photoresist layer is deposited over the seed layer, exposed, developed and cured to form a pattern to be plated. Electroless or electroplating is performed using the exposed portions of the seed layer to start the plating, forming a pattern according to patterns in the photoresist layer.

At step 405, the plating process continues. A second photoresist layer is deposited, exposed, and developed to pattern the first connection level conductor layer 452. By leaving the first photoresist layer in place, the second photoresist layer is used without an intervening photoresist strip and clean step, to simplify processing. The first trace level conductor layer 451 can be used as a seed layer for the second plating operation, to further simplify processing, as another sputter process is not performed at this step.

At step 407, a first dielectric deposition is performed. The first trace level conductor layer 451 and the first connection level conductor layer 452 are covered in a dielectric material 461. In an example a thermoplastic material is used, in a particular example ABF is used; in alternative examples ABS or ASA can be used, or a thermoset epoxy resin mold compound can be used; resins, epoxies, or plastics can be used. In an example dielectric deposition process using ABF, a roll film form of ABF can be used. The ABF is laminated over the trace level conductor 451 and the connection level conductor 453, and in a thermal process at an elevated temperature and under vacuum, the ABF softens and conforms to the conductor layers to fill the spaces with dielectric, without voids. The dielectric material 461 can then be cured to harden the material for subsequent processes.

At step 409, a grinding operation is performed on the surface of the dielectric material 461. The grinding operation exposes a surface of the connection level conductor layer 452 and provides conductive surfaces for mounting devices, or for use in additional plating operations. If the multilayer package substrate is complete at this step, the method ends at step 410, where a de-carrier operation removes the carrier 471 from the dielectric material 461, leaving the first trace level conductor layer 451 and the first connection level conductor layer 452 in a dielectric material 461, providing a multilayer package substrate.

In examples where additional trace level conductor layers and additional connection level conductor layers are needed, the method continues, leaving step 409 and transitioning to step 411 in FIG. 4B. The multilayer package substrate is now on carrier 471 with first trace level conductor layer 451 and first connection level conductor layer 452 in dielectric material 461.

At step 411, a second trace level conductor layer 453 is formed by plating using the same processes as described above with respect to step 405. An additional seed layer for the additional plating operation is deposited and a photoresist layer is deposited and patterned, and the plating operation forms the second trace level conductor layer 453 over the dielectric material 461, with portions of the second trace level conductor layer 453 electrically connected to the first connection level conductor layer 452.

At step 413, a second connection level conductor layer 454 is formed using an additional plating step on the second trace level conductor layer 453. The second connection level conductor layer 454 can be plated using the second trace level conductor layer 453 as a seed layer, and without the need for removing the preceding photoresist layer, simplifying the process.

At step 415, a second dielectric deposition operation is performed to cover the second trace level conductor layer 453 and the second connection level conductor layer 454 in a layer of dielectric 463. The multilayer package substrate at this stage has a first trace level conductor layer 451, a first connection level conductor layer 452, a second trace level conductor layer 453, and a second connection level conductor layer 454, portions of the layers are electrically connected together to form conductive paths through the dielectric materials 461 and 463.

At step 417, the dielectric layer 463 is mechanically ground in a grinding process or is chemically etched to expose a surface of the second connection level conductor layer 454. At step 419 the example method ends by removing the carrier 471, leaving a multilayer package substrate including the trace level conductor layers 451, 453, and connection level conductor layers 452 and 454 in dielectric layers 461, 463. The steps of FIGS. 4A-4B can be repeated to form multilayer package substrates for use with the arrangements having more layers, by performing plating of a trace level conductor layer, plating of a connection level conductor layer, adding additional dielectric material covering the layers, and grinding, repeatedly.

Useful sizes for an example of the multilayer package substrate could be from two to seven millimeters wide by two to seven millimeters long, for example. The size of the multilayer package substrate can be varied depending on the size and number of semiconductor devices mounted, as well as the size and number of the passive components, so that the area of the device side surface is sufficient for mounting the semiconductor devices and for mounting the passive components spaced from the semiconductor devices. In an example arrangement, 0402 capacitors having lengths of approximately 1 millimeter, and having widths of approximately 0.5 millimeters, can be mounted to the multilayer package substrate and coupled to trace level conductors or connection level conductors in or on the multilayer package substrate. Other sizes and types of passive components can be used.

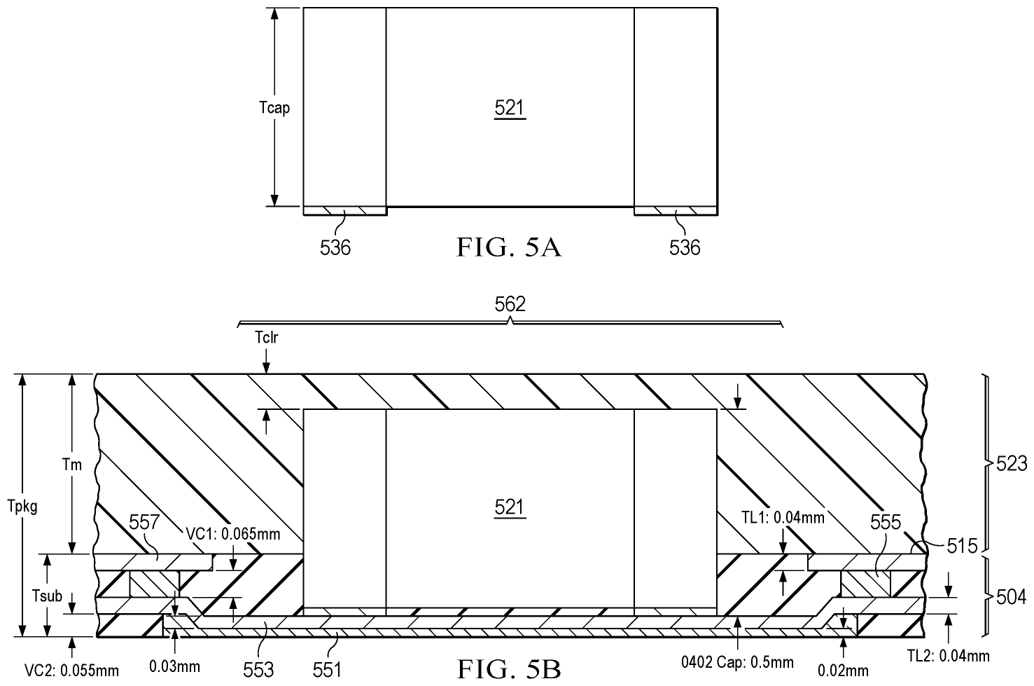

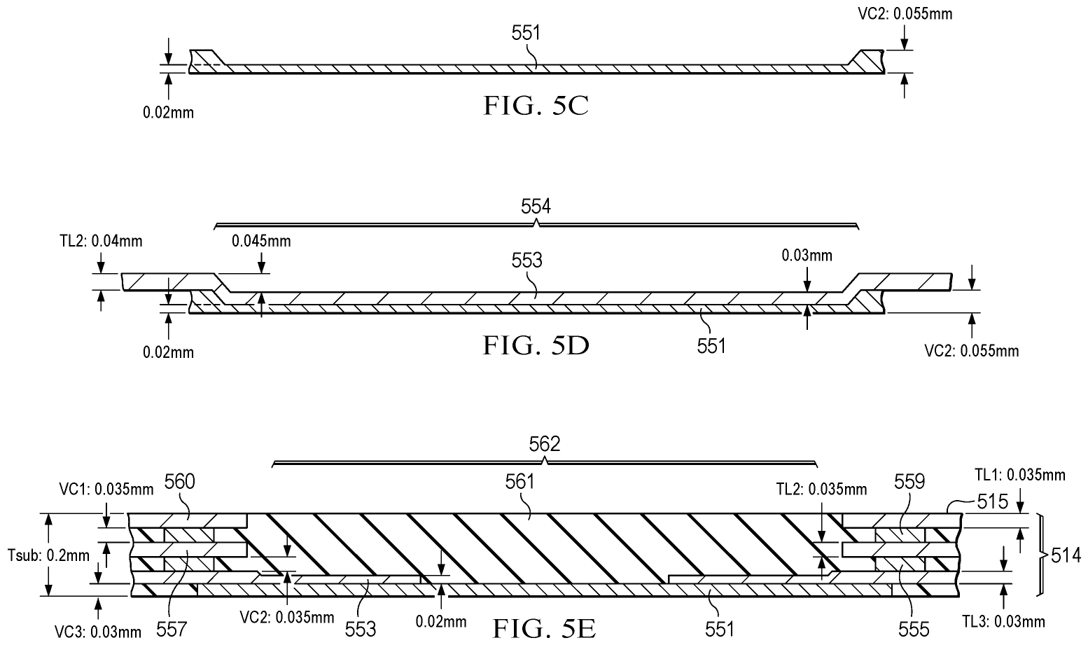

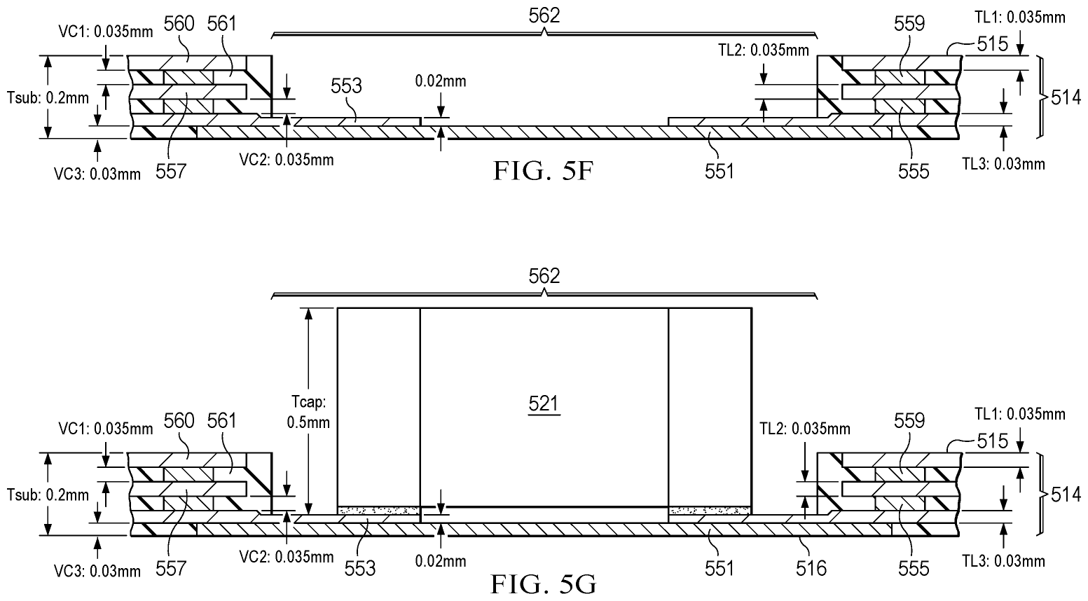

FIG. 5A illustrates, in a cross-sectional view, a two-terminal capacitor 521 that can be used with the arrangements. The capacitor 521 has studs 536 for solder mounting, each coupled to a conductive plate, and a dielectric core between the plates. In some example arrangements, the capacitor 521 is mounted without the studs 536, to further reduce the mold compound thickness needed to cover the passive component. The capacitor thickness labeled “Tcap” can be, in a particular example, about 0.5 millimeters. A type of capacitor that is useful in particular arrangements is a 0402 capacitor, which has a thickness of about 0.02 inches, or 0.5 millimeters, and a length of about 0.04 inches, or 1 millimeter. 0402 capacitors are standard sized packaged components that are configured for solder mounting, and in example arrangements, are mounted within and integral to microelectronic device packages. Other types and sizes of capacitors can be used, and additional arrangements can include other types of passive components including resistors, inductors, coils, transducers, sensors and diodes.

FIG. 5B illustrates in a cross-sectional view a particular example arrangement with some dimensions shown, here a two-level multilayer package substrate 504 that was formed using steps similar to those shown in FIGS. 4A-4B is used. The multilayer package substrate 504 has a substrate thickness labeled “Tsub” that includes the thicknesses of a first trace level conductor 557 with thickness labeled “TL1” of 0.04 mm, a first connection level conductor 555, with a thickness labeled “VC1” of 0.65 mm, a second trace level conductor 553, with a thickness labeled “TL2” of 0.04 mm, and a second connection level conductor 551 with a thickness labeled “VC2” of 0.055 mm. The total substrate thickness labeled “Tsub” in this example would be a sum of these four thicknesses VC2, TL2, VC1, and TL1, or about 0.2 mm.

The capacitor 521 of FIG. 5A is shown mounted to the second trace level conductor 553, in a recess 562 extending into the multilayer package substrate 504 from the device side surface 515. The mold compound 523 is shown covering the passive component capacitor 521 by a clearance thickness labeled “Tclr”, which provides a clearance thickness to ensure the mold compound sufficiently covers the capacitor 521, the clearance thickness Tclr can be about 0.1 millimeter, for example. A semiconductor die, not visible in the illustrated figure, is mounted to the device side surface 515 of the multilayer package substrate 504 spaced from the capacitor 521, and can be coupled to the passive component by the conductors in the multilayer package substrate 504. The semiconductor die is also covered by the mold compound 523. The semiconductor die has a thickness that is less than a thickness of the capacitor 521.

A shown in the cross-sectional view of FIG. 5B, the capacitor 521 is mounted in a recess 562 in the multilayer package substrate 504, which reduces the height that the capacitor 521 extends above the device side surface 515 of the multilayer package substrate 504 (when compared to mounting the capacitor 521 to a multilayer or other package substrate at the device side surface, as might be done without use of the arrangements). Accordingly, by use of the arrangements, the mold compound 523 thickness, labeled “Tm”, can be reduced, for example, it can be as little as 0.45 mm, and can be reduced still further if the semiconductor dies and passive components have smaller thicknesses in future devices. The total package thickness, labeled “Tpkg” in FIG. 5B, can then be about 0.65 mm, or even less. The example capacitor 521 has a thickness of 0.5 millimeters, so that the use of the arrangements enables a mold compound thickness “Tm” that is less than the thickness of the capacitor 521 (for example, 0.5 mm); which was not possible with prior approaches for making packages without use of the arrangements. A clearance thickness “Tclr” is shown above the capacitor 521, this minimum thickness insures the mold compound reliably covers the capacitor 521. In an example this thickness Tclr is 0.085 mm.

FIG. 5C illustrates a particular example of a recessed portion of a low level conductor in a multilayer package substrate that can be used in an arrangement. In the example, the lowest conductor layer in a two-level multilayer package substrate is connection level conductor 551, with a thickness labeled “VC2” of about 0.055 mm. This connection layer conductor can be formed by a plating process as is illustrated in FIGS. 4A-4B and as described above. After the connection level conductor 551 is formed, etching can be used to thin a portion of the conductor layer 551 and form a recessed portion with reduced thickness, for example a thickness of 0.02 mm, as shown in FIG. 5C.

FIG. 5D then illustrates how a subsequent plated conductor layer 553 is formed over the conductor layer 551. The subsequent plated conductor layer 553 is a trace level conductor with an example thickness labeled “TL2” of about 0.04 mm. The trace level conductor layer 553 is formed over the previously formed conductor layer 551 by plating, and as is shown in FIG. 5D, the recessed portion of the conductor layer 551 transfers to the trace level conductor layer 553, so that a recess 554 with a depth of 0.045 mm, in this example, is formed.

FIG. 5E illustrates a three-layer multilayer package substrate 514 including layers 551, and 553, of FIG. 5D, after additional process steps. The dielectric material 561, which can be ABF, ABS, ASA or another thermoplastic material, or another dielectric material, is deposited and additional conductor layers 557, 557, 559 and 560 are plated onto the layers 551, 553 using the build-up manufacturing processes illustrated in FIGS. 4A-4B and described above. A recess 562 that exposes the lower conductor layers (lower than the device side surface 515 of the multilayer package substrate 514) is shown filled with the dielectric material 561. In the example package substrate 514 of FIG. 5E, a three-level multilayer package substrate is shown with three trace level conductors 553, 557, 560 and three connection level conductors 551, 555, 559 extending between the trace level conductors through the dielectric material 561. In comparison, in FIG. 5B a two-level package substrate (see 504 in FIG. 5B) is shown.

FIG. 5F illustrates the multilayer package substrate 514 of FIG. 5E after a dielectric etch step removes dielectric material 561 from the recess 562, exposing portions of the trace level conductor 553 for mounting a passive component extending into the multilayer package substrate 514 from the device side surface 515.

FIG. 5G illustrates the capacitor 521 of FIG. 5A, for example, mounted to the lower-level conductor 553, a trace level conductor of the multilayer package substrate 514, using solder. The capacitor 521 is a two-terminal device. In the illustrated example an 0402 capacitor is shown. An 0402 capacitor typically includes mounts for solder mounting, however, in an alternative arrangement these mounts are removed, and a solder connection is made to the conductors of the body of the capacitor directly, this optional step can further reduce the component height extending from device side surface of the multilayer package substrate. The thickness of the multilayer package substrate 514, labeled “Ts”, can be around 0.2 mm in an example where the three trace level conductors 560, 557, 553 have thicknesses labeled “TL1”, “TL2”, and “TL3” of 0.035, 0.035, and 0.03 mm, and the connection level conductors 559, 555, and 551 have thicknesses labeled “VC1”, “VC2”, and “VC3” of 0.035, 0.035 and 0.03 mm. The capacitor 521 has a thickness labeled “Tcap” of about 0.5 mm. By placing the passive component into the recess 562 of the multilayer package substrate, the amount the passive component extends above the device side surface 515 of the multilayer package substrate 514 is reduced, which enables the use of a thinner mold compound in the arrangements. After a molding step, the elements of FIG. 5G will form the arrangement of FIG. 5B, for example, with mold compound 523 over the multilayer package substrate 504, and the capacitor 521.

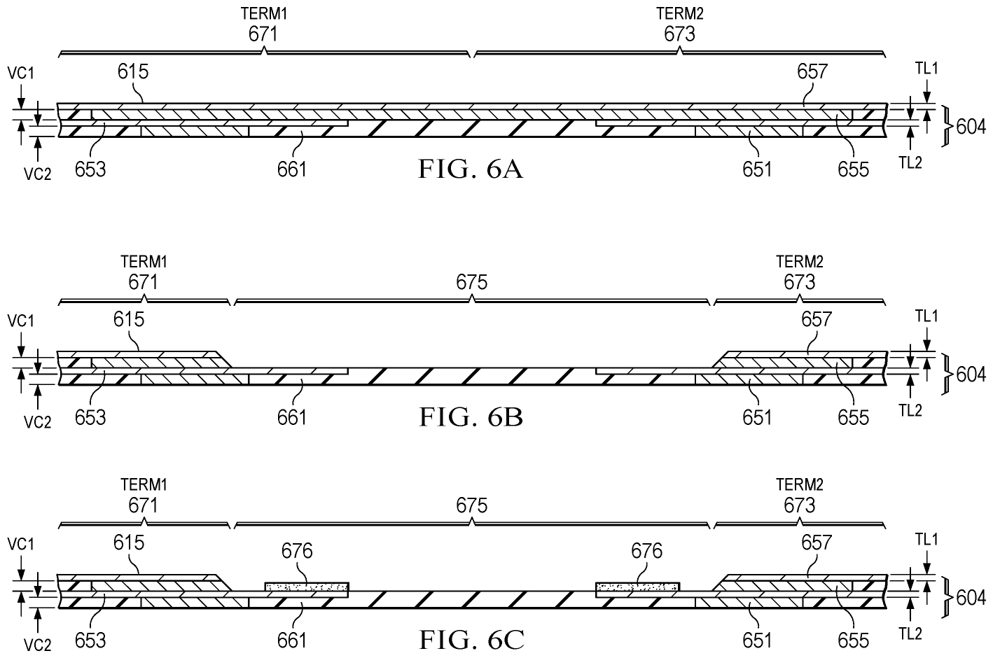

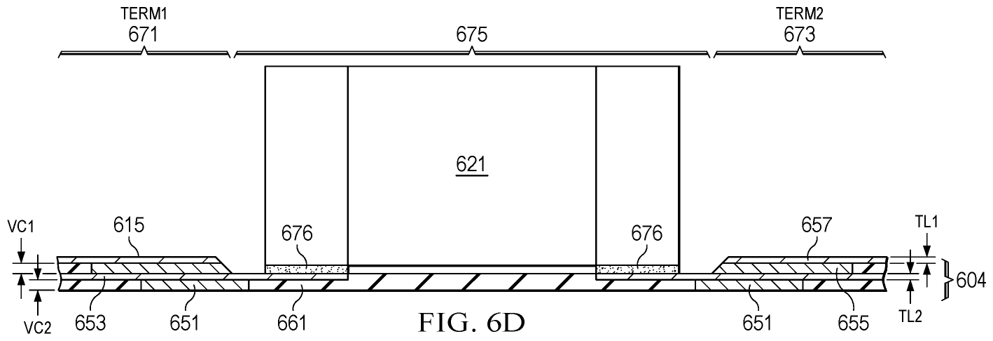

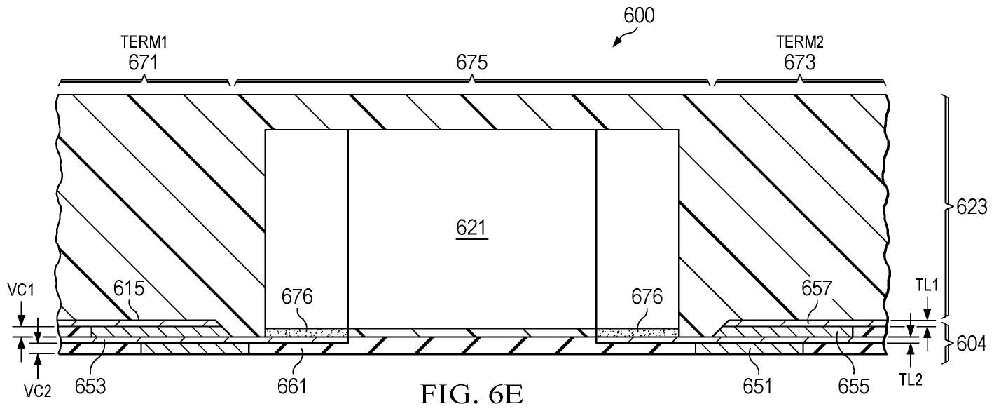

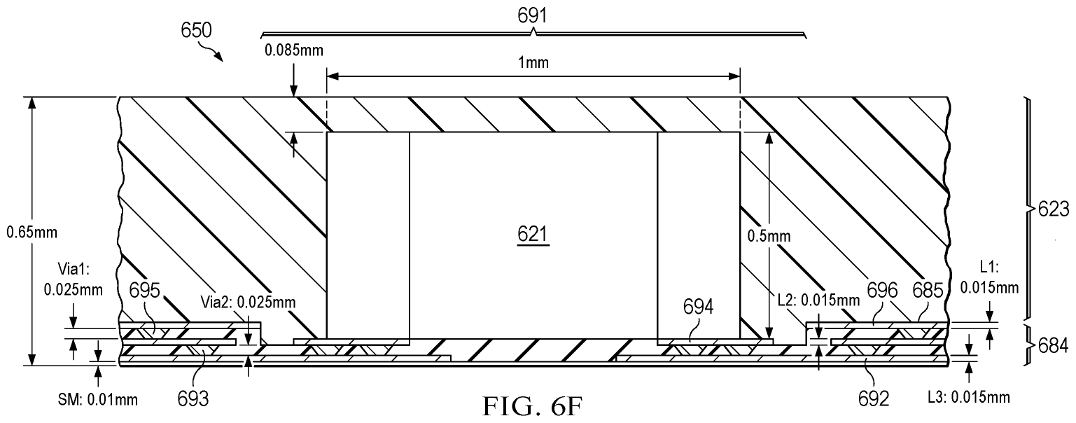

FIGS. 6A-6E illustrate, in a series of cross-sectional views, steps for forming an alternative arrangement with a recessed portion of a multilayer package substrate. FIG. 6F illustrates an additional arrangement with a recessed portion of an example using an ETS package substrate.

FIG. 6A illustrates a multilayer package substrate 604 including two trace level conductor layers 657, 655 with thicknesses labeled “TL1”, “TL2”, and two connection level conductor layers 653, 651 with thicknesses labeled “VC1”, “VC2”, extending through the dielectric material 661, which can be ABF, ABS, ASA, epoxy resin mold compound, or another dielectric material. The multilayer package substrate 604 is similar to the multilayer package substrates described above and can be made in a build-up manufacturing process as shown in FIGS. 4A-4B, for example. In the multilayer package substrate 604 as shown in FIG. 6A, two terminals are formed, labeled “TERM1” (numbered 671), and “TERM2” (numbered 673), and may be configured as two conductors that are to be coupled to a capacitor, or to another two terminal passive component. As shown in FIG. 6A, after the conductor layers are formed in the build-up plating process, the two terminals 671, 673 are shorted together at the device side surface 615 of the multilayer package substrate 604. This is accomplished by patterning the trace level conductor layer 657 (with thickness TL1) as a continuous conductor shorting the two terminals. At other conductor layers lower in the multilayer package substrate 604 (lower than the device side surface 615), the two terminals 671, 673 are spaced from one another by the dielectric material 661 of the multilayer package substrate 604. For example the trace level conductor 653, with the thickness TL2, is shown with the dielectric 661 spacing the portions for TERM1 and TERM2 apart.

FIG. 6B illustrates the multilayer package substrate 604 after a metal etch step cuts through some of the upper conductor layers to form a recess 675 extending into the multilayer package substrate 604 from the device side surface 615. The metal etch process can be performed using photoresist, development, and patterning steps to etch the metal from the multilayer package substrate 604 and form recess 675, however a portion of the trace level conductor 653 (TL2) is left on both sides of the recess 675, providing conductors TERM1 and TERM 2 spaced apart and configured for mounting a two terminal passive component in the recess 675.

FIG. 6C illustrates, in another cross-sectional view, the multilayer package substrate 604 after solder 676 is deposited on the lower trace level conductor 653 (TL2) to prepare for mounting a passive component in the recess 675. The terminals 671 (TERM1) and 673 (TERM2) are no longer shorted, as the etch processes described above cut through the common metal conductor material previously connecting these two terminals.

FIG. 6D illustrates, in another cross-sectional view, the multilayer package substrate 604 after a passive component 621 is mounted in the recess 675. Solder 676 is used to mount the passive component 621. In an example, the passive component 621 can be a capacitor. In another example, the terminals 671 (TERM1) and 673 (TERM2) can be configured to conduct a power potential and a ground potential, so that a capacitor used as passive component 621 is coupled in a bypass circuit configuration. In a more particular example, a capacitor used as passive component 621 can be an 0402 capacitor, although other sizes and values of capacitors can be used. As shown in the example illustrated in FIG. 6D, the passive component 621 is mounted without the “studs” (see studs 536 on capacitor 521 in FIG. 5A, for example), which further reduces the thickness of the mold compound needed to cover the passive component in a later step. Alternatively, the passive component can be mounted with the studs present. Similarly, other circuit configurations can be used with capacitors, and with other passive components useful with the arrangements including resistors, inductors, coils, transducers, sensors and diodes.

FIG. 6E illustrates, in another cross-sectional view, a microelectronic device package 600 formed by performing a molding process on the multilayer package substrate 604 of FIG. 6D. FIG. 6E illustrates an arrangement similar to that shown in FIG. 3A, with additional details illustrated. A semiconductor die, not visible in the cross-section of FIG. 6E, will be mounted on the device side surface 615 of the multilayer package substrate 604 spaced from the passive component 621, and is covered with the mold compound 623. (See, for example, semiconductor die 202 in FIGS. 2A-2B). In FIG. 6E, the multilayer package substrate 604 has mold compound 623 formed over the device side surface 615. The passive component 621 is shown extending into the multilayer package substrate 604 in the recess 675 and mounted to a trace level conductor 653 that is beneath the device side surface 615 of the multilayer package substrate 604. The mold compound 623 covers the passive component 621, however due to use of the arrangements, the amount the passive component 621 extends above the device side surface of the multilayer package substrate 604 is reduced, allowing for a thinner mold compound 623 than would be the case without use of the arrangements. The arrangements shown in FIGS. 6A-6E are formed, for example, by a metal etch applied after a multilayer package substrate is formed, while the arrangements shown in FIGS. 5B-5G, in contrast, are formed by a dielectric etch after the multilayer package substrate has been formed. In both of these types of arrangements, the passive components are mounted prior to molding, or “pre-mold”, and then covered with the mold compound at the same time the semiconductor die is covered in an encapsulation molding process.

FIG. 6F illustrates another alternative arrangement for a microelectronic device package 650 formed in a “pre-mold” process. FIG. 6F illustrates a similar arrangement to FIG. 3B, with additional dimensions for a particular example. In the example arrangement shown in FIG. 6F, an ETS package substrate 684 is used. ETS package substrates have trace conductors formed, in an example, by an electroless plating process. Prepreg dielectric layers, which can be glass reinforced fiber or another mesh or material carrying an epoxy or resin, are used to form dielectric material between the trace conductor layers. Vias are drilled into the dielectric layers between plating operations, and the vias fill with conductor material when the trace conductor layers are plated. By repeatedly forming vias, plating conductor layers, and applying the prepreg material to form dielectric layers, an ETS substrate with multiple trace layers and conductive vias can be formed. The ETS package substrate 684 illustrated in FIG. 6F has three trace conductor layers 692, 694, and 696, with thicknesses L1, L2, L3 of 0.015 millimeters. The ETS substrate 684 includes via layers 693, 695 of thickness Via1, Via2 of 0.025 millimeters. The ETS substrate 684 thus has a total thickness of about 0.105 millimeters. In the illustrated example, the passive component 621 is a 0402 capacitor with a 0.5-millimeter thickness. A clearance thickness Tclr in FIG. 6B is 0.085 millimeters, by placing the 0.5-millimeter-thick capacitor 621 in the recess in the ETS substrate, the total package thickness of 0.65 millimeters can be achieved using a 0.45-millimeter-thick mold compound 623. The recess 691 in the ETS substrate 684 can be formed using a laser ablation process, where laser energy removes the prepreg dielectric material from the device side surface 685 to expose the trace conductors of the trace level conductor 694, where the passive component (the capacitor) can be solder mounted. The mold compound 623 covers the passive component and a semiconductor die (not shown in the cross-section of FIG. 6B) with a reduced mold compound thickness (when compared to packages formed with passive components without use of the arrangements.)

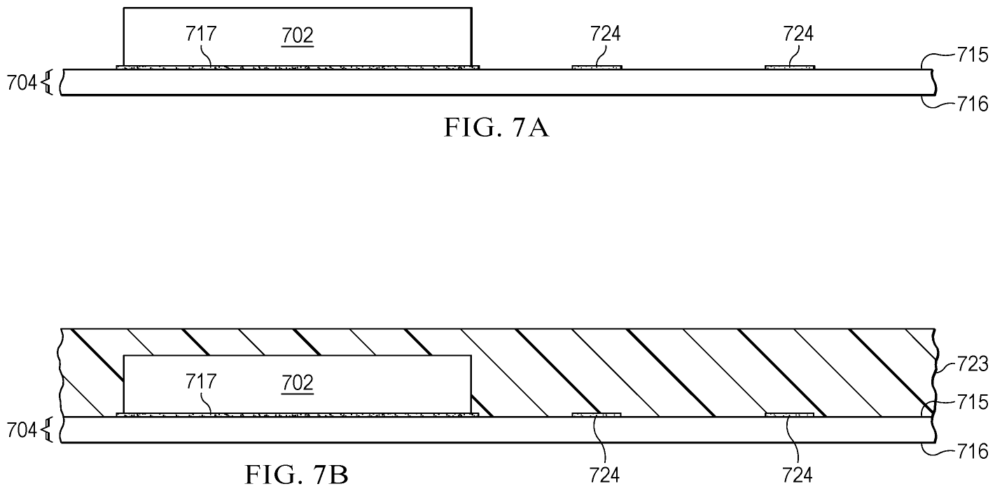

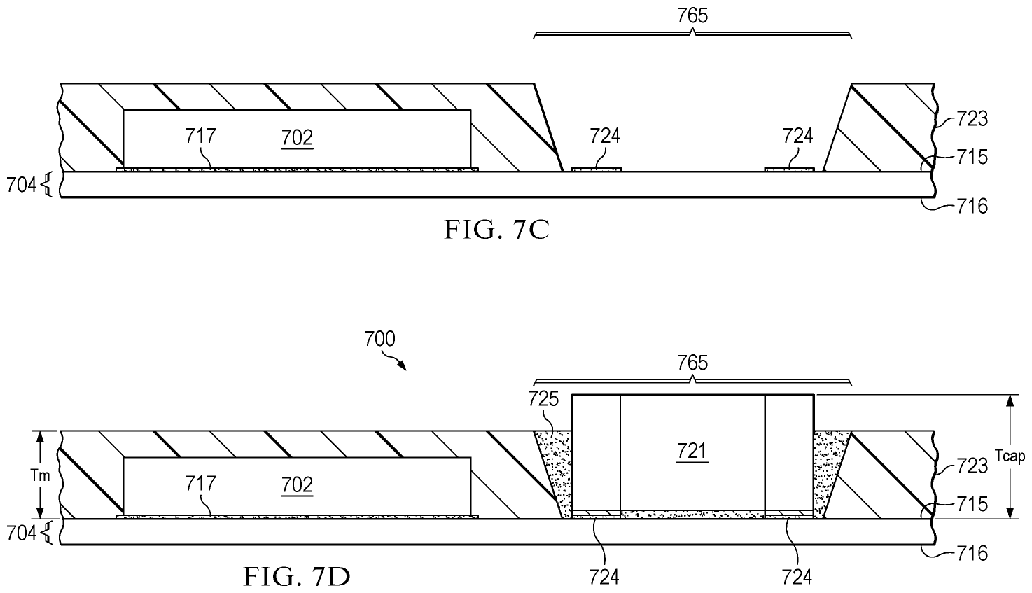

FIGS. 7A-7D illustrate, in an alternative approach, cross-sectional views for another arrangement. In FIGS. 7A-7D, selected steps for forming an arrangement for a “post-mold” passive component mount to a package substrate for a microelectronic device package are shown.

FIG. 7A illustrates a cross-sectional view of a package substrate 704. Because, in the post-mold arrangements, a recess is not needed in the package substrate, package substrates such as conductive lead frames, including partially etched, half etched or premolded lead frames (PMLFs), can be used. In alternative arrangements multilayer package substrates as described above with respect to FIGS. 5A-5G and FIGS. 6A-6E can be used, and molded interconnect substrates (MIS) and ETS substrates can be used. Semiconductor die 702 is shown flip chip mounted on a device side surface 715 of the package substrate 704 using die attach 717. Solder 724 is shown on the package substrate in a portion for mounting a passive component spaced from the semiconductor die 702.

FIG. 7B illustrates, in another cross-sectional view, the package substrate 704 and semiconductor die 702 after additional processing. In FIG. 7B, mold compound 723 is shown covering the semiconductor die 702 and the package substrate 704. The mold compound 723 can be of sufficient thickness over the package substrate to cover the semiconductor die 702, which can be, for example, 0.1-0.4 mm thick.

FIG. 7C illustrates, in yet another cross-sectional view, the elements of FIG. 7B after additional processing. In FIG. 7B, a recess 765 in the mold compound 723 is formed by, in one example process, a laser ablation process. The laser ablation process applies laser energy to the mold compound in selected areas and removes the mold compound to form the recess 765, exposing the solder 724 for mounting a passive component, however, the mold compound 723 remains over the semiconductor die 702. In an example laser process, a laser can be used with a frequency of between 10-20 kilohertz, with a range of laser intensity between 20-30 Amperes. Multiple laser passes can be used to achieve the removal of the mold compound 723. Post process cleans, such as a plasma process, can be used to remove debris.

FIG. 7D illustrates, in another cross-sectional view, the elements of FIG. 7C after additional processing. In FIG. 7D, a passive component 721, which can be a capacitor for example, is mounted to the package substrate 704 in the recess 765, and solder 724 is used to couple the terminals for the passive component 721 to the package substrate 704. The passive component 721 is shown in the recess 765, an optional solder fill material 725 is shown deposited around the passive component 721 to protect the device and to protect the solder connections to the package substrate 704.

As shown in FIG. 7D, the passive component 721 can have a thickness labeled “Tcap” that is greater than the mold compound thickness labeled “Tm.”. Because, in the “post-mold” arrangements, the passive component 721 is mounted after the semiconductor die 702 is protected by the mold compound 723, the thickness of the mold compound 723 is no longer restrained by the thickness of the passive component 721, the use of the arrangements advantageously allowing a thinner mold compound 723 thickness Tm with corresponding reduced mold stress, and increased package reliability.

The arrangement for a microelectronic device package 700 shown in FIG. 7D differs from the arrangements shown in FIGS. 2A-2C and FIGS. 3A-3B, for example, in that the passive component is mounted “post-mold” in FIGS. 7A-7D, that is after a molding step. In contrast, the passive components are mounted “pre-mold” for the arrangements in FIGS. 2A-2B and FIGS. 3A-3B, that is prior to a molding step, and in those pre-mold arrangements the mold compound covers the thickness of the passive component, and the mold compound thickness includes a clearance thickness over the passive component. In a “post-mold” example using a 0402 capacitor with a 0.5 mm thickness, a 0.45 mm mold compound layer was formed over a metal lead frame, providing a microelectronic device package with a thin mold compound layer, reducing mold compound stress. In an example, a 0.65-millimeter package thickness was achieved with a 0.2-millimeter-thick package substrate and the 0.45-millimeter mold compound thickness. Molding of the semiconductor die and package substrate is done prior to the mounting of the passive component so that the molding process and the mold tools are not impacted by thickness of the passive component, and because the laser ablation step is done “post-mold”, as is the mounting of the passive component, existing mold tools can be used to form the arrangements.

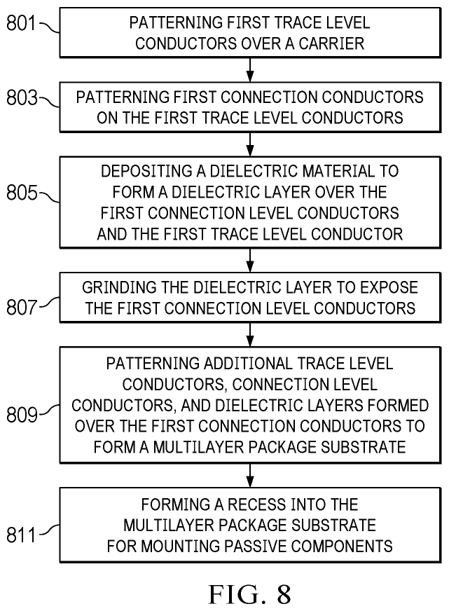

FIG. 8 illustrates, in a flow diagram, the steps used to form a multilayer package substrate for use in the arrangements. At step 801, the first trace level conductors are patterned over a carrier (see, for example, trace level conductors 451 in FIG. 4A, step 403). At step 803, the first connection level conductors are patterned onto the trace level conductors (see, for example, the first connection level conductors 452 in FIG. 4A, step 405). At step 805, a dielectric material is deposited to form a dielectric layer over the first connection level conductors and the first trace level conductors. (See, for example, the dielectric layer 461 in FIG. 4A, at step 407). At step 807, the method continues by grinding the dielectric layer to expose the first connection level conductors (see, for example, step 409 in FIG. 4A). At step 809, additional trace level conductors and connection level conductors are patterned over the first connection level conductors to form a multilayer package substrate. (See, for example, FIG. 4B, steps 411-419).

At step 811, the method continues and forms a recess into the device side surface of the multilayer package substrate for mounting passive components (see, for example, recess 562 in FIG. 5F, and as another example recess, 675 in FIG. 6C). For some arrangements, the forming of the recess is a dielectric etch step (see FIGS. 5A-5G), while in alternative arrangements, the forming of the recess can be a metal etch step, (see, for example, FIGS. 6A-6E); or can be a laser ablation step applied to an ETS package substrate (see FIG. 6F).

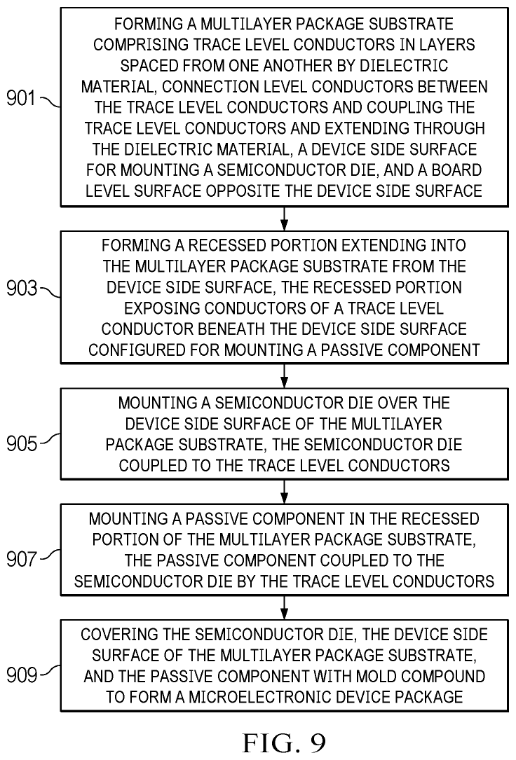

FIG. 9 illustrates, in a flow diagram, steps for forming a “pre-mold” arrangement as is shown in FIGS. 2A-2B, FIGS. 3A-3B, FIG. 5B and FIGS. 6E-6F. The method begins at step 901 by forming a multilayer package substrate. The multilayer package substrate includes trace level conductors in layers spaced from one another by dielectric material, connection level conductors between the trace level conductors and coupling the trace level conductors and extending through the dielectric material, a device side surface for mounting a semiconductor die, and a board level surface opposite the device side surface. (See, for example, the multilayer package substrate 204 in FIG. 2A.)

At step 903, the method continues by forming a recessed portion extending into the multilayer package substrate from the device side surface, the recessed portion exposing conductors of a trace level conductor beneath the device side surface configured for mounting a passive component, (see, for example, the recess 562 in the multilayer package substrate 514 in FIG. 5F; see also the recess 675 in the multilayer package substrate 604 in FIG. 6C).

At step 905, the method continues by mounting a semiconductor die over the device side surface of the multilayer package substrate, the semiconductor die coupled to the trace level conductors. (See, for example, the semiconductor die 202 in FIGS. 2A-2B). At step 907, the method continues by mounting a passive component in the recessed portion of the multilayer package substrate, the passive component coupled to the semiconductor die by the trace level conductors (see, for example, capacitor 521 in FIG. 5G, and the passive component 621 in FIG. 6D).

At step 909, the semiconductor die, the device side surface of the multilayer package substrate, and the passive component are covered with mold compound to form a microelectronic device package. (See, for example, FIG. 5B, showing mold compound 523 over package substrate 504 in the microelectronic device package, and FIG. 6E, with the mold compound 623 over the package substrate 604, and covering the passive component 621).

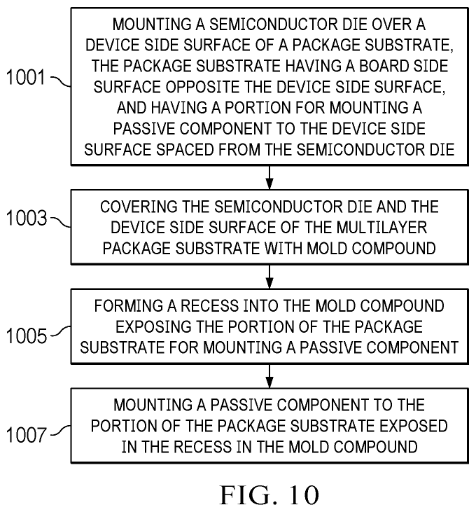

FIG. 10 illustrates, in a flow diagram, selected steps for forming a “post-mold” arrangement, such as shown in FIG. 7D, where a passive component is mounted to a package substrate, such as a lead frame, after molding.

In FIG. 10 the method begins at step 1001, by mounting a semiconductor die over a device side surface of a package substrate, the package substrate having a board side surface opposite the device side surface, and having a portion for mounting a passive component to the device side surface spaced from the semiconductor die. (See, for example, semiconductor die 702 in FIG. 7A).

At step 1003, the method continues by covering the semiconductor die and the device side surface of the multilayer package substrate with mold compound. (See, for example, mold compound 723 in FIG. 7B). At step 1005, the method continues by forming a recess into the mold compound exposing the portion of the package substrate for mounting a passive component.

At step 1007, the method completes by mounting the passive component to the portion of the package substrate that is exposed in the recess in the mold compound. (See, for example, the passive component 721 mounted to the package substrate 704 in FIG. 7D).

The use of the arrangements provides microelectronic device packages including a semiconductor die with an integral passive component, or components. Existing materials and assembly tools are used to form the arrangements, and the arrangements are low in cost. The use of the arrangements allows for a thinner mold compound and resulting reduced mold compound stress and increased reliability, when compared to solutions formed without use of the arrangements.

Modifications are possible in the described arrangements, and other alternative arrangements are possible within the scope of the claims.

What is claimed is:

1. A microelectronic device package, comprising:
a multilayer package substrate comprising trace level conductors spaced by dielectric material, the multilayer package substrate having a device side surface and an opposing board side surface, and having a recess extending from the device side surface and exposing selected ones of the trace level conductors beneath the device side surface of the multilayer package substrate;
a semiconductor die mounted to the device side surface of the multilayer package substrate and coupled to the trace level conductors;
a passive component mounted to the selected ones of the trace level conductors exposed in the recess in the multilayer package substrate; and
mold compound covering the semiconductor die, the passive component, and a portion of the multilayer package substrate.

2. The microelectronic device package of claim 1, wherein the semiconductor die comprises a power field effect transistor (FET) device.

3. The microelectronic device package of claim 1, wherein the passive component comprises a two-terminal device.

4. The microelectronic device package of claim 1, wherein the passive component comprises a capacitor, an inductor, a coil, a resistor, a diode or a sensor.

5. The microelectronic device package of claim 1, wherein the passive component comprises a capacitor.

6. The microelectronic device package of claim 5, wherein the capacitor has a capacitor thickness that is greater than a thickness of the semiconductor die.

7. The microelectronic device package of claim 5, wherein the capacitor has a thickness of about 0.5 millimeters.

8. The microelectronic device package of claim 5, wherein the passive component is an 0402 capacitor.

9. The microelectronic device package of claim 5, wherein the capacitor has a capacitor thickness that is greater than a thickness of the mold compound over the device side surface of the multilayer package substrate.

10. The microelectronic device package of claim 1, wherein the multilayer package substrate comprises the trace level conductors spaced from one another by the dielectric material, and further comprises connection level conductors between layers of the trace level conductors, the connection level conductors extending through the dielectric material to couple the trace level conductors.

11. The microelectronic device package of claim 1, wherein the dielectric material comprises Ajinomoto build-up film (ABF).

12. The microelectronic device package of claim 1, wherein the dielectric material comprises Ajinomoto build-up film (ABF), acrylonitrile butadiene styrene (ABS), acrylonitrile styrene acrylate (ASA), or resin epoxy.

13. The microelectronic device package of claim 1, wherein the multilayer package substrate comprises an embedded trace substrate (ETS) and the dielectric material comprises a prepreg material.

14. The microelectronic device package of claim 1, wherein the multilayer package substrate has a substrate thickness from the device side surface to the board side surface of about 0.2 millimeters, the mold compound over the device side surface has a mold compound thickness of about 0.45 millimeters, and the microelectronic device package has a total thickness equal to or less than 0.65 millimeters.

15. The microelectronic device package of claim 1, wherein the semiconductor die is flip chip mounted to the device side surface of the multilayer package substrate, the semiconductor die having conductive post connects extending from bond pads on the semiconductor die and extending to distal ends away from the semiconductor die, and having solder bumps on the distal ends of the conductive post connects, the solder bumps forming solder joints to the package substrate.

16. The microelectronic device package of claim 1, wherein the microelectronic device package further comprises a quad flat no-lead (QFN) package.

17. A microelectronic device package, comprising:
a package substrate having a device side surface and an opposing board side surface, and having a portion configured for mounting a passive component on the device side surface;
a semiconductor die mounted to the device side surface of the package substrate;
mold compound covering the device side surface of the package substrate and covering the semiconductor die;
a recess extending into the mold compound exposing the portion of the package substrate configured for mounting the passive component on the device side surface; and
a passive component mounted to the portion of the package substrate in the recess in the mold compound, the passive component coupled to the semiconductor die.

18. The microelectronic device package of claim 17, and further comprising solder fill material deposited in the recess in the mold compound and surrounding the passive component.

19. The microelectronic device package of claim 17, wherein the passive component has a thickness greater than the thickness of the mold compound.

20. The microelectronic device package of claim 17 wherein the passive component is a capacitor, an inductor, a coil, a resistor, a diode or a sensor.

21. The microelectronic device package of claim 17, wherein the passive component is an 0402 capacitor with a thickness of about 0.5 millimeters.

22. The microelectronic device package of claim 17, wherein the package substrate has a substrate thickness less than or equal to 0.2 millimeters, the mold compound has a mold compound thickness less than or equal to 0.45 millimeters, and the passive component has a passive component thickness greater than about 0.4 millimeters.

23. A method, comprising:
forming a multilayer package substrate comprising trace level conductors in layers spaced from one another by dielectric material, connection level conductors between the trace level conductors extending through the dielectric material and coupling the trace level conductors, and a device side surface configured for mounting a semiconductor die, and having a board side surface opposite the device side surface;
forming a recessed portion extending into the multilayer package substrate from the device side surface, the recessed portion exposing portions of a selected one of the trace level conductors beneath the device side surface, the portions configured for mounting a passive component;
mounting a semiconductor die over the device side surface of the multilayer package substrate, the semiconductor die coupled to the trace level conductors;
mounting a passive component to the portions of the selected one of the trace level conductors in the recessed portion of the multilayer package substrate, the passive component coupled to the semiconductor die by the trace level conductors; and
covering the semiconductor die, the device side surface of the multilayer package substrate, and the passive component with mold compound to form a microelectronic device package.

24. The method of claim 23, wherein forming the multilayer package substrate further comprises:
patterning first trace level conductors over a carrier;
patterning first connection level conductors over the first trace level conductors;
depositing a first dielectric material over the first connection level conductors and the first trace level conductors;
grinding the first dielectric material to expose the first connection level conductors;
etching the first connection level conductors to form a recess in a portion of the first connection level conductors;
patterning additional trace level conductors, additional connection level conductors, and forming additional dielectric layers over the first connection level conductors to form the multilayer package substrate, with the additional dielectric layers covering the recess in the portion of the first connection level conductors; and
forming a recessed portion further comprises performing a dielectric etch to remove the additional dielectric layers from the recess to expose portions of the first connection level conductors configured to mount the passive component.

25. The method of claim 23 wherein mounting a passive component further comprises mounting a two-terminal passive component.

26. The method of claim 25 wherein the two-terminal passive component is a capacitor.

27. The method of claim 25 wherein the two-terminal passive component is capacitor having a capacitor thickness of at least 0.5 millimeters.

28. The method of claim 23 where the microelectronic device package has a total package thickness from the board side surface of the multilayer package substrate to a top surface of the mold compound that is less than or equal to 0.65 mm.

29. The method of claim 23 wherein forming the multilayer package substrate further comprises:
patterning first trace level conductors over a carrier;
patterning first connection level conductors over the first trace level conductors;
depositing a first dielectric material over the first connection level conductors and the first trace level conductors;
grinding the first dielectric material to expose the first connection level conductors;
patterning additional trace level conductors, additional connection level conductors, and forming additional dielectric material over the first connection level conductors to form the multilayer package substrate, with selected trace level conductors at the device side surface of the multilayer package substrate forming a shorted portion with a first terminal and a second terminal shorted together at the device side surface, the first terminal and the second terminal including additional trace level conductors spaced from one another by the dielectric material in the multilayer package substrate beneath the device side surface; and
performing a metal etch into the device side surface to a depth to cut through the shorted portion, forming a recess in the multilayer package substrate for mounting the passive component to the first terminal and the second terminal.

30. The method of claim 29 wherein mounting a passive component further comprises mounting a capacitor.

31. The method of claim 30 wherein the capacitor has a thickness of at least 0.5 mm.

32. The method of claim 29, wherein the microelectronics device package has a package thickness from the board side surface of the multilayer package substrate to a top surface of the mold compound of less than or equal to 0.65 mm.

33. The method of claim 23, wherein forming a multilayer package substrate further comprises forming an embedded trace substrate (ETS) with conductors forming the trace level conductors spaced from one another by a prepreg material that is the dielectric material, and having conductive vias forming the connection level conductors between the trace level conductors extending through the prepreg dielectric material, and wherein forming the recessed portion further comprises performing a laser ablation on the device side surface of the ETS.

34. A method, comprising:
mounting a semiconductor die over a device side surface of a package substrate, the package substrate having a board side surface opposite the device side surface, and having a portion configured for mounting a passive component to the device side surface spaced from the semiconductor die;
covering the semiconductor die and the device side surface of the multilayer package substrate with mold compound;
forming a recess into the mold compound exposing the portion of the package substrate configured for mounting a passive component; and
mounting a passive component to the portion of the package substrate exposed in the recess in the mold compound.

35. The method of claim 34, wherein forming the recess into the mold compound comprises forming using laser ablation or an etch.

36. The method of claim 34, and further comprising depositing solder fill material in the recess into the mold compound surrounding the passive component.
